(19) United States
(12) Patent Application Publication
(10) Pub. No.: US 2023/0389250 A1
(43) Pub. Date: Nov. 30, 2023

(54) COMPONENT SUPPLY DEVICE, COMPONENT SUPPLY METHOD, AND PROGRAM

(71) Applicant: Konica Minolta, Inc., Tokyo (JP)

(72) Inventors: Akihiro Nakamura, Toyokawa-shi (JP); Yasuyuki Kamai, Tokyo (JP); Yusuke Murakami, Tokyo (JP); Akira Tsunoda, Yokohama-shi (JP)

(21) Appl. No.: 18/135,221

(22) Filed: Apr. 17, 2023

(30) Foreign Application Priority Data
May 30, 2022 (JP) 2022-087410

(51) Int. Cl. H05K 13/08; H05K 13/04; B25J 9/16

(52) U.S. Cl. CPC H05K 13/0812; H05K 13/0404; B25J 9/1612; B25J 9/1697

(57) ABSTRACT

A component supply device includes: a picker base on which a component is to be loaded; a supplier that picks up the component loaded on the picker base and supplies the component to a predetermined position; a detector that detects the component loaded on the picker base; and a hardware processor that determines a state of the component loaded on the picker base, on a basis of information detected by the detector, wherein the hardware processor determines whether the component is a component that is pickable or a component that is unpickable by the supplier on a basis of the state of the component, and calculates an operation amount for adjusting the component that is unpickable to a pickable state and adjusts only a state of the component that is unpickable by an adjuster on a basis of the calculated operation amount.

The entire disclosure of Japanese patent Application No. 2022-087410, filed on May 30, 2022, is incorporated herein by reference in its entirety.

### BACKGROUND

### Technological Field

The present invention relates to a component supply device, a component supply method, and a program.

### Description of the Related Art

In recent years, there has been proposed a component supply device that takes out a small amount of components from stacked components and supplies the components to a predetermined position. Techniques of this type in related art include, for example, those described in JP 2018-8343 A. JP 2018-8343 A describes a technique in which, on a tray on which components are placed, in a case where the components overlap each other and cannot be grasped by a robot hand, the tray is tilted to break the overlap of the components.

However, even if the tray is tilted, a component does not necessarily move to a posture or a position where the component can be picked. Thus, in the technique described in JP 2018-8343 A, it is necessary to move the component many times, which degrades efficiency of component pickup operation.

### SUMMARY

In view of the problem in related art as described above, an object of the present invention is to provide a component supply device, a component supply method, and a program capable of improving efficiency of component pickup operation.

To achieve the abovementioned object, according to an aspect of the present invention, a component supply device reflecting one aspect of the present invention comprises: a picker base on which a component is to be loaded; a supplier that picks up the component loaded on the picker base and supplies the component to a predetermined position; a detector that detects the component loaded on the picker base; and a hardware processor that determines a state of the component loaded on the picker base, on a basis of information detected by the detector, wherein the hardware processor determines whether the component is a component that is pickable or a component that is unpickable by the supplier on a basis of the state of the component, and calculates an operation amount for adjusting the component that is unpickable to a pickable state and adjusts only a state of the component that is unpickable by an adjuster on a basis of the calculated operation amount.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are not intended as a definition of the limits of the present invention:

FIG. 1 is a perspective view of a component supply device according to an embodiment of the present invention;

FIG. 2 is a top view of the component supply device according to the embodiment of the present invention;

FIG. 3 is a side view of the component supply device according to the embodiment of the present invention;

FIG. 4 is a side view of a supplier in the component supply device according to the embodiment of the present invention;

FIG. 5 is a perspective view of a hand of the supplier in the component supply device according to the embodiment of the present invention;

FIG. 6 is a perspective view of a picker base in the component supply device according to the embodiment of the present invention;

FIG. 7 is a block diagram illustrating a configuration example of a control system in the component supply device according to the embodiment of the present invention;

FIG. 8 is a block diagram illustrating a configuration example of a recognition controller in the component supply device according to the embodiment of the present invention;

FIG. 9 is a view for explaining component supply operation of the component supply device according to the embodiment of the present invention;

FIG. 10 is a flowchart illustrating an example of pickup operation in the component supply device according to the embodiment of the present invention;

FIG. 11 is a flowchart illustrating preliminary preparation processing of the pickup operation in the component supply device according to the embodiment of the present invention;

FIG. 12 is an explanatory diagram illustrating whether or not picking is possible in a component posture;

FIG. 13 is a flowchart illustrating component state determination processing of the pickup operation in the component supply device according to the embodiment of the present invention;

FIG. 14 is an explanatory diagram illustrating an example of the component state determination processing;

FIG. 15A is a graph indicating a relationship between a component region and an area, and FIG. 15B is a view illustrating the component region;

FIG. 16 is a flowchart illustrating interference determination processing of the pickup operation in the component supply device according to the embodiment of the present invention;

FIGS. 17A and 17B are explanatory diagrams illustrating the interference determination processing;

FIG. 18 is an explanatory diagram illustrating ellipse fitting processing;

FIG. 19 is a flowchart illustrating processing of determining whether or not rearrangement (position) is possible in the pickup operation in the component supply device according to the embodiment of the present invention;

FIG. 20 is an explanatory diagram illustrating the processing of determining whether or not rearrangement (position) is possible;

FIG. 21 is an explanatory diagram illustrating the processing of determining whether or not rearrangement (position) is possible;

FIG. 22 is a flowchart illustrating the processing of determining whether or not rearrangement (posture/position) is possible in the pickup operation in the component supply device according to the embodiment of the present invention;

FIG. 23 is a flowchart illustrating region division processing of the pickup operation in the component supply device according to the embodiment of the present invention; and

FIG. 24 is an explanatory diagram illustrating the region division processing.

### DETAILED DESCRIPTION OF EMBODIMENTS

Hereinafter, one or more embodiments of the present invention will be described with reference to the drawings. However, the scope of the invention is not limited to the disclosed embodiments. In the drawings, the same members are denoted by the same reference numerals.

[Configuration of Component Supply Device]

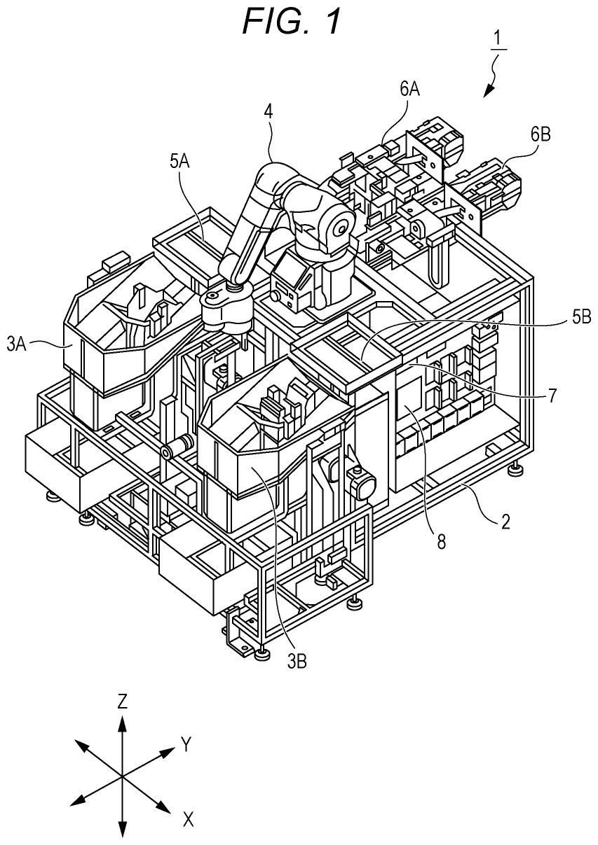

First, a configuration of a component supply device according to an embodiment will be described with reference to FIGS. 1 to 3.

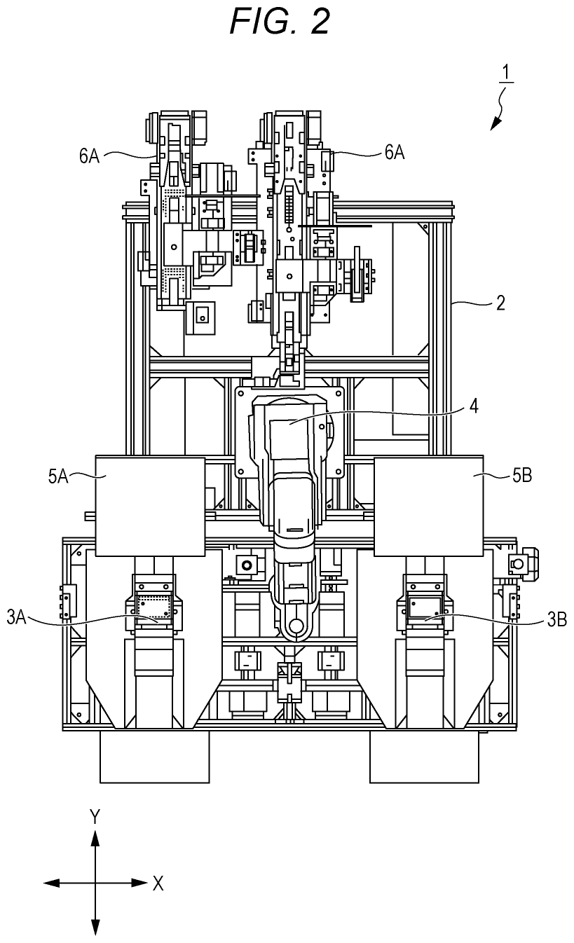

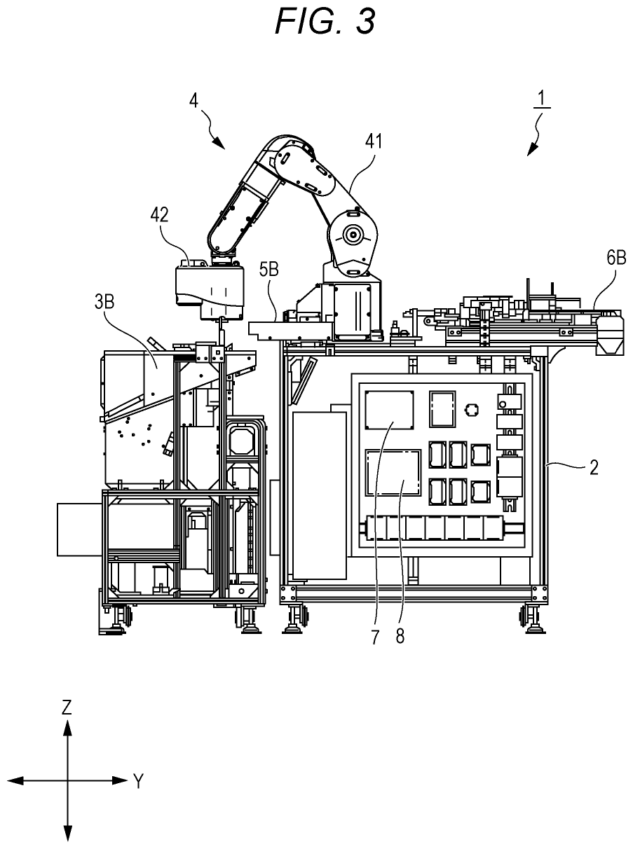

FIG. 1 is a perspective view of the component supply device. FIG. 2 is a top view of the component supply device. FIG. 3 is a side view of the component supply device.

As illustrated in FIG. 1, the component supply device 1 includes a frame 2, storages 3A and 3B, a supplier 4, picker bases 5A and 5B, place tables 6A and 6B, and a control board 7. The storages 3A and 3B, the supplier 4, the picker bases 5A and 5B, the place tables 6A and 6B, and the control board 7 are attached to the frame 2. The component supply device 1 arranges components stored in the storages 3A and 3B while aligning postures thereof with the place tables 6A and 6B and supplies the components to a device in the next step.

The frame 2 is formed in a substantially rectangular parallelepiped shape and has a width, a depth, and a height. In FIGS. 1 to 3, an X-axis direction indicates a width direction of the frame 2, a Y-axis direction indicates a depth direction of the frame 2, and a Z-axis direction indicates a height direction of the frame 2. The X-axis direction and the Y-axis direction correspond to horizontal biaxial directions which are two axial directions parallel to a horizontal plane, and the Z-axis direction corresponds to a vertical direction which is a direction orthogonal to the horizontal plane. The frame 2 includes a horizontal member extending in the X-axis direction or the Y-axis direction and a vertical member extending in the Z-axis direction.

The storages 3A and 3B are arranged on one side of the frame 2 in the Y axis direction. The storages 3A and 3B face each other with an appropriate distance in the X-axis direction. The storages 3A and 3B are formed in a substantially box shape with an open upper surface. The storages 3A and 3B are provided with a lifting mechanism that moves bottom parts in the Z-axis direction. This allows change of capacity and a height position of the stored component of each of the storages 3A and 3B.

For example, a first component is stored in the storage 3A, and a second component different from the first component is stored in the storage 3B. The component supply device 1 in this case supplies the first component and the second component to the device in the next step. In addition, the first component may be stored in the storages 3A and 3B in a first period, and the second component may be stored in the storages 3A and 3B in a second period different from the first period. The component supply device 1 in this case supplies the first component to the device in the next step in the first period and supplies the second component to the device in the next step in the second period.

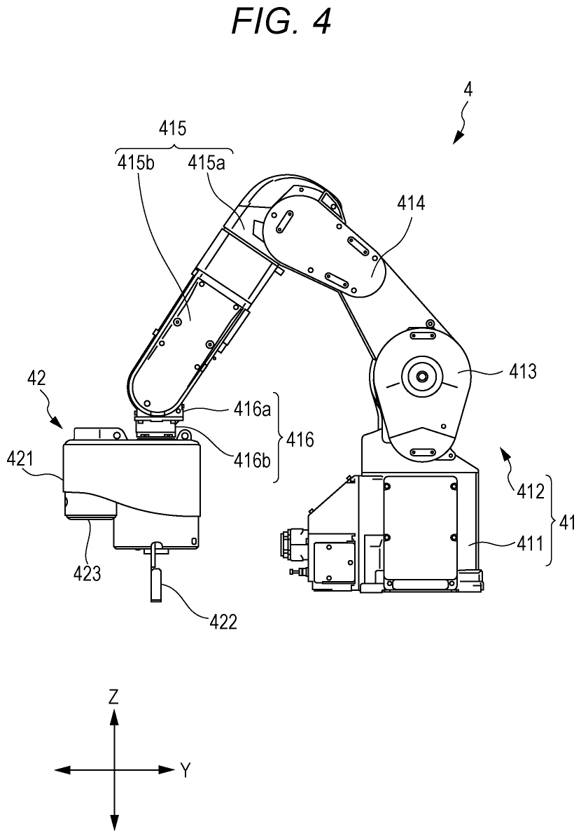

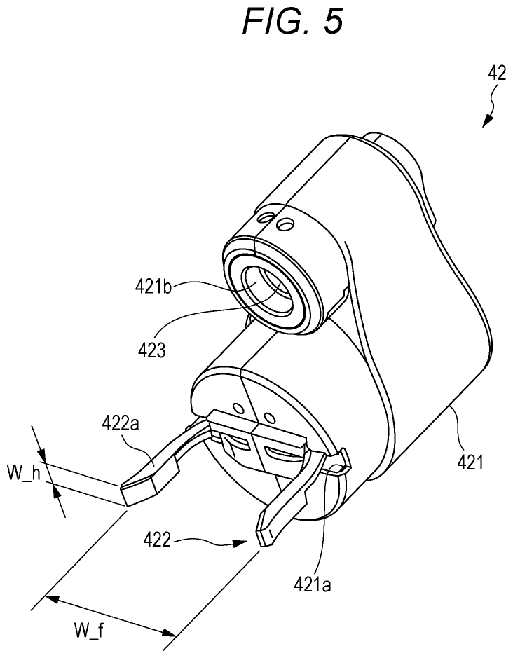

The supplier 4 is arranged at a substantially central part in an upper part of the frame 2. The supplier 4 grasps one or a plurality of components from a large number of first components or a large number of second components stored in the storages 3A and 3B and drops and supplies the components to the picker bases 5A and 5B. As a result, the first component or the second component is placed on the picker bases 5A and 5B. In addition, the supplier 4 grasps the first component or the second component placed on the picker bases 5A and 5B one by one and supplies the first component or the second component to the place tables 6A and 6B. A configuration of the supplier 4 will be described later with reference to FIGS. 4 and 5.

The picker bases 5A and 5B are arranged on both sides of the supplier 4 in the X-axis direction. The picker bases 5A and 5B are adjacent to the storages 3A and 3B in the Y-axis direction, respectively. The picker bases 5A and 5B are positioned above the storages 3A and 3B.

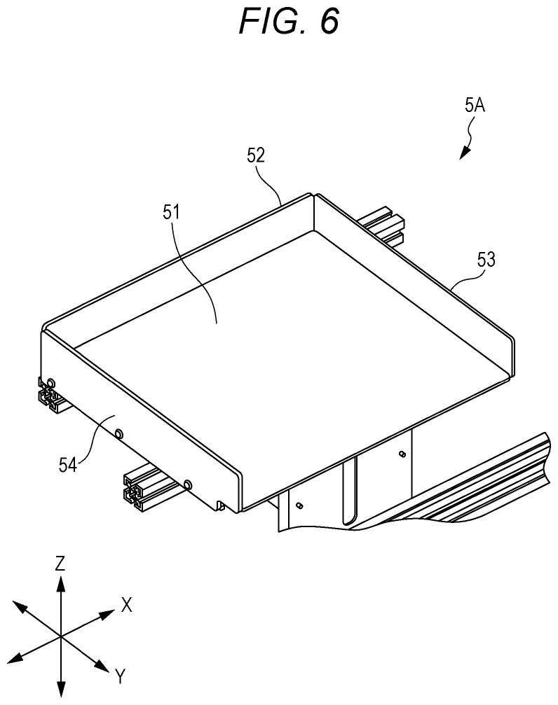

In the Z-axis direction, part of the picker base 5A overlaps the storage 3A. As a result, the component dropped from part of the picker base 5A is stored (returned) in the storage 3A. In the Z-axis direction, part of the picker base 5B overlaps the storage 3B. As a result, the component dropped from part of the picker base 5B is stored (returned) in the storage 3B. A configuration of the picker bases 5A and 5B will be described later with reference to FIG. 6.

The place tables 6A and 6B have belt conveyors that convey components in the Y-axis direction. The place tables 6A and 6B are attached to an X-axis moving mechanism. The X-axis moving mechanism moves the place tables 6A and 6B in the X-axis direction. The place tables 6A and 6B convey the components supplied from the supplier 4 in the Y-axis direction and position the components at a predetermined position. The positioned components are fed to the device in the next step.

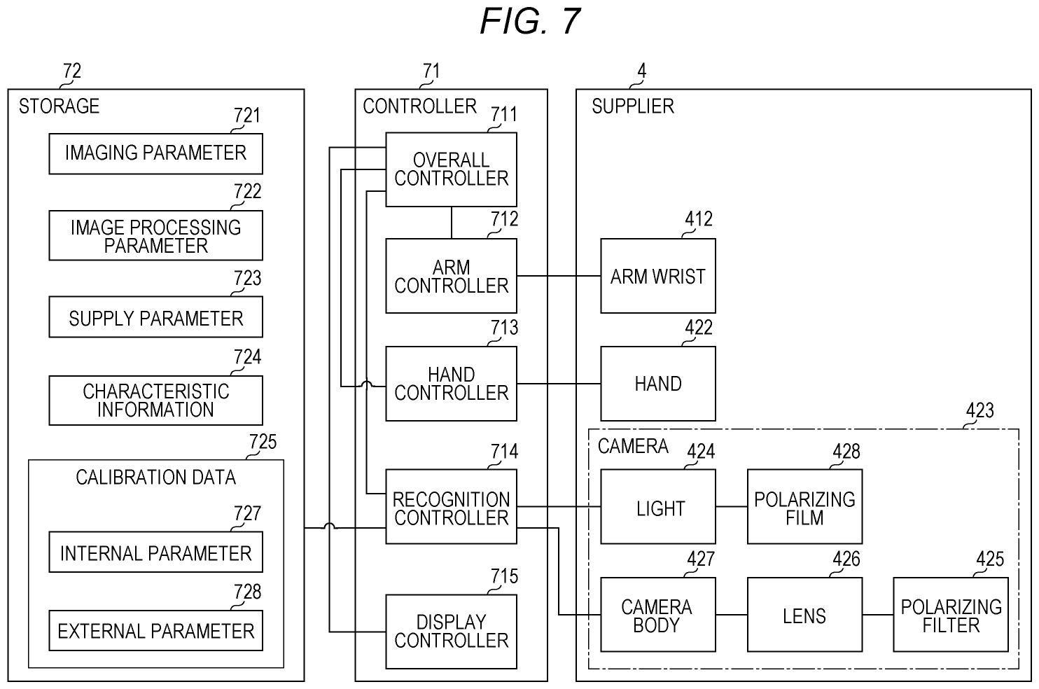

As illustrated in FIGS. 1 and 3, the control board 7 is attached to a side of the frame 2. The control board 7 is provided with a controller 71 (see FIG. 7) that controls operation of the storages 3A and 3B, the supplier 4, and the place tables 6A and 6B.

[Configuration of Supplier]

Next, the configuration of the supplier 4 will be described with reference to FIGS. 4 and 5.

FIG. 4 is a side view of the supplier 4 in the component supply device 1. FIG. 5 is a perspective view of a hand of the supplier 4 in the component supply device 1.

As illustrated in FIG. 4, the supplier 4 includes an arm block 41 and a hand block 42 connected to the arm block 41. The arm block 41 includes a support base 411 and an arm 412 attached to the support base 411. The support base 411 is fixed to the frame 2. The support base 411 rotatably supports the arm 412.

The arm 412 freely moves the hand block 42 in the X-axis direction, the Y-axis direction, and the Z-axis direction. The arm 412 freely rotates the hand block 42 about the X axis, the Y axis, and the Z axis. The arm 412 includes a base member 413, a first link member 414, a second link member 415, and a connection member 416.

The base member 413 is rotatably connected to the support base 411. The base member 413 rotates about the Z axis (first axis). One end of the first link member 414 is rotatably connected to the base member 413. The first link member 414 rotates about an axis (second axis) extending in the horizontal direction.

The second link member 415 includes a rotator 415a and a turner 415b connected to the rotator 415a. The rotator 415a is rotatably connected to the other end of the first link member 414. The rotator 415a rotates about an axis (third axis) extending in the horizontal direction. The turner 415b is rotatably connected to the rotator 415a. The turner 415b rotates about an axis (fourth axis) extending in a connection direction with the rotator 415a.

The connection member 416 includes a rotator 416a and a turner 416b connected to the rotator 416a. The rotator 416a is rotatably connected to the turner 415b of the second link member 415. The rotator 416a rotates about an axis (fifth axis) extending in the horizontal direction. The turner 416b is rotatably connected to the rotator 416a. The turner 416b rotates about an axis (sixth axis) extending in a connection direction with the rotator 416a. Note that directions in which the second axis, the third axis, and the fourth axis extend are parallel.

As illustrated in FIG. 5, the hand block 42 includes a housing 421, and a hand 422 and a camera 423 attached to the housing 421. The housing 421 is connected to the turner 416b of the connection member 416 in the arm 412. The housing 421 is a substantially rectangular parallelepiped housing. A hand hole 421a through which the hand 422 passes and a lens hole 421b through which an objective lens of the camera 423 is exposed are formed in a lower surface of the housing 421.

The hand 422 includes a plurality of (two in the present embodiment) grasping pieces 422a. An opening and closing mechanism for opening and closing the plurality of grasping pieces 422a and a lifting mechanism for lifting and lowering the plurality of grasping pieces are disposed inside the housing 421. The plurality of grasping pieces 422a is lifted and lowered by the lifting mechanism, so that a length of the grasping pieces protruding from the hand hole 421a changes. If the length of the plurality of grasping pieces 422a protruding from the hand hole 421a is increased, a space for holding the components is widened, and the number of components to be grasped is increased. On the other hand, if the length of the plurality of grasping pieces 422a protruding from the hand hole 421a is shortened, the space for holding the components is narrowed, and the number of components to be grasped is reduced.

The plurality of grasping pieces 422a can grasp one component at a tip thereof. The hand 422 grasps one or a plurality of components from a large number of components stored in the storage 3A or the storage 3B and supplies the components to the picker base 5A or the picker base 5B. On the other hand, the hand 422 grasps one component from one or a plurality of components placed on the picker base 5A or the picker base 5B and supplies the one component to the place table 6A or the place table 6B.

The length of the grasping pieces 422a in a width direction (a width of the hand fingertip) is set to W_h. An interval (finger opening width) in a state where the two grasping pieces 422a are opened is set to W_f. Information on the hand fingertip width W_h and the finger opening width W_f of the grasping pieces 422a is stored in a storage 72 described later.

The camera 423 is a specific example of a detector according to the present invention. The camera 423 includes an image sensor, a plurality of lenses including an objective lens, a polarizing filter, illumination, and the like. The camera 423 is housed in the housing 421. The objective lens of the camera 423 is exposed from the lens hole 421b of the housing 421.

An image (video) captured by the camera 423 is transmitted to a controller 71 described later. The controller 71 detects information such as positions of the storages 3A and 3B and the picker bases 5A and 5B from the image captured by the camera 423.

[Configuration of Picker Base]

Next, a configuration of the picker bases 5A and 5B will be described with reference to FIG. 6.

FIG. 6 is a perspective view of the picker base 5A in the component supply device 1.

The picker bases 5A and 5B have the same configuration. Thus, here, the configuration of the picker base 5A will be described as an example. As illustrated in FIG. 6, the picker base 5A includes a tray 51 forming a loading surface and three wall plates 52 to 54 continuous with the tray 51.

The tray 51 is constituted with a substantially quadrangular plate. A plane of the tray 51 is substantially orthogonal to the Z-axis direction. The tray 51 has two sides substantially parallel to the X-axis direction and two sides substantially parallel to the Y-axis direction. The wall plate 52 protrudes substantially perpendicularly from a side far from the storage 3A (see FIG. 2) out of two sides substantially parallel to the X-axis direction in the tray 51. The wall plates 53 and 54 protrude substantially vertically from two sides of the tray 51 substantially parallel to the Y-axis direction.

The wall plates 52 to 54 prevent the supplied component from falling from the tray 51. The side of the tray 51 on which the wall plate is not provided overlaps an opening of the storage 3A in the Z-axis direction. As a result, the component dropped from the side of the tray 51 on which the wall plate is not provided returns to the storage 3A. A tilting mechanism for tilting the picker base 5A is provided below the picker base 5A. The tilting mechanism tilts the picker base 5A such that the wall plate 52 side becomes higher. As a result, the component placed on the picker base 5A drops from the side of the tray 51 on which the wall plate is not provided and is collected in the storage 3A.

[Configuration of Control System]

Next, a configuration of a control system of the component supply device 1 will be described with reference to FIG. 7.

FIG. 7 is a block diagram illustrating a configuration example of the control system in the component supply device 1.

The control board 7 (see FIG. 1) is provided with a controller 71 and a storage 72. The controller 71 includes a central processing unit (CPU), a read only memory (ROM), and a random access memory (RAM). Various functions of the controller 71 are implemented by the CPU executing a predetermined processing program stored in the ROM. The various functions of the controller 71 include, for example, operation control of the arm 412 by an arm controller 712 and operation control of the hand 422 by a hand controller 713.

As illustrated in FIG. 7, the controller 71 includes an overall controller 711, the arm controller 712, the hand controller 713, and a recognition controller 714. The controller 71 is a specific example of a supply adjuster according to the present invention.

The overall controller 711 is connected to the arm controller 712, the hand controller 713, and the recognition controller 714. The overall controller 711 receives, from the recognition controller 714, detection results such as positions of the storages 3A and 3B, the hand 422, and the like, the sizes of the picker bases 5A and the number of components grasped by the hand 422.

The overall controller 711 performs overall control of the arm controller 712 and the hand controller 713 on the basis of the detection results received from the recognition controller 714 and a supply parameter 723 and characteristic information 724 stored in the storage 72.

The arm controller 712 is connected to a driver of the arm 412. The arm controller 712 receives a control command from the overall controller 711. The arm controller 712 generates an arm drive signal for driving the arm 412 on the basis of the control command received from the overall controller 711 and transmits the arm drive signal to the driver of the arm 412. As a result, the arm 412 executes operation according to the control command of the overall controller 711.

The hand controller 713 is connected to a driver of the hand 422. The hand controller 713 receives a control command from the overall controller 711. The hand controller 713 generates a hand drive signal for driving the hand 422 on the basis of the control command received from the overall controller 711 and transmits the hand drive signal to the driver of the hand 422. As a result, the hand 422 executes operation according to the control command of the overall controller 711.

The recognition controller 714 is connected to the camera 423. The recognition controller 714 controls imaging by the camera 423 on the basis of an imaging parameter 721 stored in the storage 72. Furthermore, the recognition controller 714 performs image processing on the image data received from the camera 423 on the basis of image processing parameters (various correction values) stored in the storage 72.

The recognition controller 714 detects positions of the storages 3A and 3B, the picker bases 5A and 5B, and the place tables 6A and 6B from the image data subjected to the image processing. The recognition controller 714 detects a posture of the hand 422 and the number of components grasped by the hand 422 from the image data subjected to the image processing. In addition, the recognition controller 714 detects sizes (areas) of the picker bases 5A and 5B, shapes (presence or absence of wall plates) of the picker bases 5A and 5B, outer shapes (contours) of components placed on the picker bases 5A and 5B, and the like, from the image data subjected to the image processing. Then, the recognition controller 714 transmits the detection results to the overall controller 711.

The storage 72 stores the imaging parameter 721, an image processing parameter 722, the supply parameter 723, the characteristic information 724, and calibration data 725. The imaging parameter 721 is used when an image of each part (such as the picker bases 5A, 5B) is captured by the camera 423. Examples of the imaging parameter include an exposure period, a light amount of illumination, an image size, and the like, according to an imaging target. The image processing parameter 722 is various correction values to be used when image processing is performed on the image data received from the camera 423.

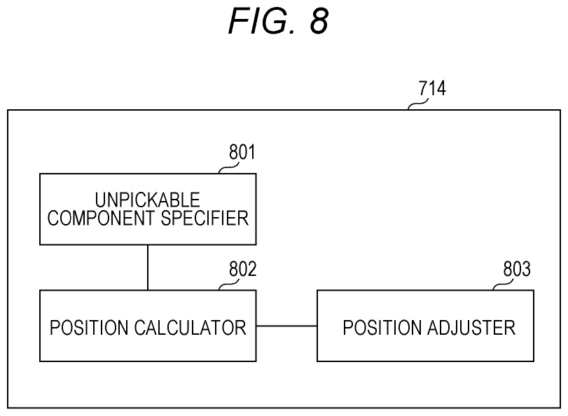

The supply parameter 723 is used to determine operation of the supplier 4 when a component is supplied to the picker base 5A or the picker base 5B. The supply parameter 723 is stored in the storage 72 in advance. The supply parameter 723 is prepared according to the characteristic information to be described later. The content of the supply parameter 723 will be described later with reference to FIG. 8.

The characteristic information 724 is information of at least one of a shape of the component, a weight of the component, a gravity center position of the component, a material of the component, surface property of the component, a surface friction coefficient of the component, or color of the component. The characteristic information 724 is stored in the storage 72 in advance for each type of component. Note that the controller 71 may extract the characteristic information 724 from 3D model data of the component. In this case, the 3D model data of the component is stored in advance in the storage 72.

The calibration data 725 includes an internal parameter 727 that is a focal length and a distortion correction parameter of a camera body 427, and an external parameter 728 for conversion from a coordinate system with the camera body 427 as an origin to a coordinate system that can be handled by the supplier 4.

Next, a configuration of the recognition controller 714 will be described with reference to FIG. 8.

FIG. 8 is a block diagram illustrating a configuration of the recognition controller 714.

As illustrated in FIG. 8, the recognition controller 714 includes an unpickable component specifier 801, a position calculator 802, and a position adjuster 803. The unpickable component specifier 801 specifies a component that cannot be grasped (picked) by the hand 422 among the components placed on the picker bases 5A and 5B on the basis of the image data. Then, the unpickable component specifier 801 transmits information on the specified component to the position calculator 802.

The position calculator 802 calculates the position of the component specified by the unpickable component specifier 801. Then, the position calculator 802 transmits information on the calculated position of the unpickable component to the position adjuster 803. The position adjuster 803 calculates a movement amount (adjustment amount) for bringing the component into a pickable position and posture on the basis of the position information of the unpickable component calculated by the position calculator 802. Then, the position adjuster 803 transmits the calculated movement amount to the overall controller 711. The overall controller 711 outputs a control command to the arm controller 712 and the hand controller 713 on the basis of the movement information for rearrangement received from the position adjuster 803 and controls the operation of the supplier 4.

Although the example in which the unpickable component specifier 801, the position calculator 802, and the position adjuster 803 are provided in the recognition controller 714 has been described, the present invention is not limited thereto. For example, the unpickable component specifier 801, the position calculator 802, and the position adjuster 803 may be provided in the overall controller 711 or may be individually provided in the controller 71.

[Component Supply Operation of Component Supply Device]

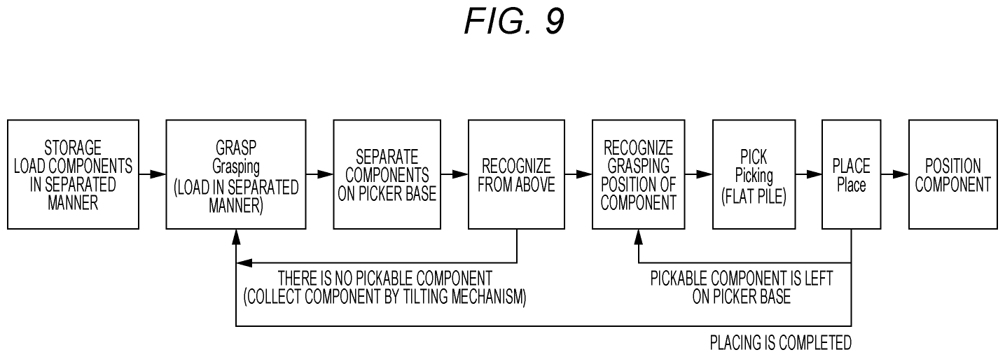

Next, component supply operation of the component supply device 1 will be described with reference to FIG. 9.

FIG. 9 is a view for explaining the component supply operation of the component supply device 1.

As illustrated in FIG. 9, in order for the component supply device 1 to supply components to a device in the next step, first, the components are stored in the storages 3A and 3B (hereinafter, referred to as a “storage 3”). The components may be stored in the storage 3 by a device in the preceding step or by a person.

Next, the supplier 4 grasps one or a plurality of components from a large number of components in the storage 3 and supplies the components to the picker bases 5A or 5B (hereinafter, a “picker base 5”). In this event, the supplier 4 performs supply operation such that the grasped components are separated on the picker base 5. Hereinafter, the supply operation in which the components are separated on the picker base 5 will be referred to as “component separation operation”.

Next, the camera 423 captures an image of the picker base 5, and the recognition controller 714 of the controller 71 recognizes the picker base 5 from above. In this event, the recognition controller 714 determines whether or not there is a component that can be grasped on the picker base 5.

In a case where a component is placed on the picker base 5 but the component is at a position or in a posture that cannot be grasped by the supplier 4, the component (unpickable component) is specified. Then, the position of the unpickable component is calculated, and an amount of movement to a position where the unpickable component can be grasped by the supplier 4 is calculated. The unpickable component is rearranged by the supplier 4 or another device on the basis of the calculated movement amount.

In addition, in a case where the unpickable component cannot be rearranged, the tilting mechanism is driven to tilt the picker base 5. As a result, the component placed on the picker base 5 drops from the side of the tray 51 on which the wall plate is not provided and is collected in the storage 3.

In a case where it is determined that there is a component that can be grasped on the picker base 5, the recognition controller 714 recognizes (determines) a grasping position for grasping one of the components on the picker base 5. Then, the supplier 4 grasps one component and supplies the component to the place tables 6A and 6B (hereinafter, referred to as a “place table 6”). The place table 6 positions the supplied component at a predetermined position. The component positioned at the predetermined position is supplied to the device in the next step.

If the supplier 4 supplies one component to the place table 6, the recognition controller 714 recognizes (determines) a grasping position for grasping the next one of the components on the picker base 5. In this event, if there is no component on the picker base 5, the operation of supplying components to the place table 6 is terminated. Then, the supplier 4 grasps one or more components from a large number of components in the storage 3.

[Example of Pickup Operation of Supplier]

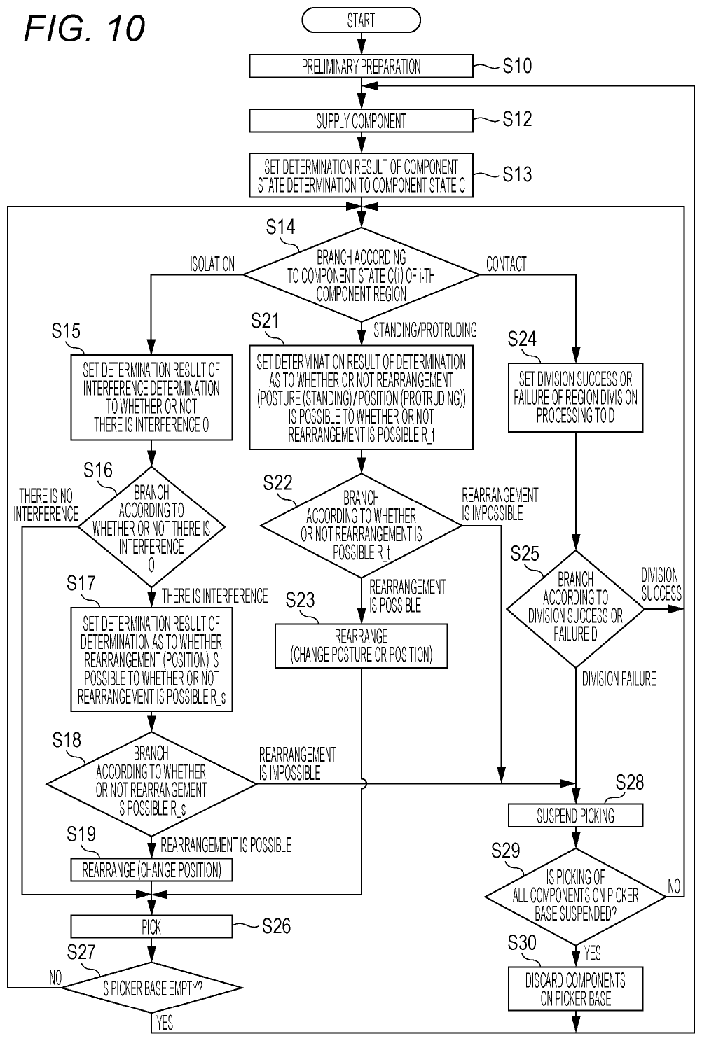

Next, pickup operation example in the supplier 4 will be described with reference to FIGS. 10 to 24.

FIG. 10 is a flowchart illustrating an example of the pickup operation.

As illustrated in FIG. 10, first, preliminary preparation is performed before the supplier 4 picks a component (step S10). In the preliminary preparation processing, information on the components to be handled and the hand 422 is stored in the storage 72. Note that the preliminary preparation in step S10 will be described in detail later.

Next, the supplier 4 grasps the components from the storage 3 and supplies the components to the tray 51 of the picker base 5 (step S12). Then, an image of the tray 51 is captured by the camera 423 of the supplier 4, and the controller 71 determines a state of the components loaded on the tray 51 (step S13). In step S13, the controller 71 sets the determination result to a component state C. Examples of the component state C include “isolation” in which each of the components is isolated as one component, “standing/protruding” in which each of the components is isolated as one component but a posture is incorrect (standing) or protrudes from the tray 51, and “contact” in which the components are in contact with each other. Note that the processing of determining the component state according to step S13 will be described in detail later.

Next, the controller 71 determines whether a component state C(i) of an i-th component region is “isolation”, “contact”, or “standing/protruding” on the basis of the component state determined in step S13 (step S14). In a case where it is determined that the component state is “isolation” in the processing of step S14, the controller 71 performs interference determination (step S15). In step S15, the controller 71 sets the determination result to whether or not there is interference O. The interference determination processing in step S15 will be described in detail later.

Next, the controller 71 determines whether, whether or not there is interference O determined in step S15 indicates “there is interference” or “there is no interference” (step S16). In a case where it is determined that “there is no interference” in the processing of step S16, the controller 71 controls the supplier 4 and picks the component (step S26).

Furthermore, in a case where it is determined that “there is interference” in the processing of step S16, the controller 71 determines whether or not rearrangement (position) is possible (step S17). Furthermore, in step S17, the controller 71 sets the determination result to whether or not rearrangement is possible R_s. Here, whether or not rearrangement is possible R_s is “rearrangement is possible” or “rearrangement is impossible”. Note that the processing of determining whether or not rearrangement (position) is possible in step S17 will be described in detail later.

Next, the controller determines whether, whether or not rearrangement is possible R_s set in step S17 is “rearrangement is possible” or “rearrangement is impossible” (step S18). In a case where it is determined in the processing in step S18 that “rearrangement is possible”, the controller 71 controls the supplier 4 to rearrange (position change) the component (step S19) and picks the rearranged component (step S26). Note that a movement amount of the component to the rearrangement position in the processing in step S19 is calculated in the processing of determining whether or not rearrangement (position) is possible in the processing in step S17.

In a case where the processing in step S26 ends, the controller 71 determines whether or not the picker base 5 is empty (step S27). In the processing in step S27, in a case where it is determined that there is still a component on the picker base 5 (No in step S27), the processing of the controller 71 returns to the processing in step S14. In a case where it is determined in the processing in step S27 that there is no component on the picker base 5 (Yes in step S27), the processing of the controller 71 returns to the processing in step S12, and the controller 71 causes components to be supplied from the storage 3 to the picker base 5.

In addition, in a case where it is determined that “rearrangement is impossible” in the processing in step S18, the controller 71 suspends pickup operation of the component (step S28). If the processing in step S28 ends, the controller determines whether or not the pickup operation of all the components on the picker base 5 is suspended (step S29). In the processing in step S29, in a case where it is determined that the pickup operation of all the components is not suspended (No in step S29), the processing of the controller 71 returns to the processing in step S14.

On the other hand, in a case where it is determined in the processing in step S29 that the pickup operation of all the components is suspended (Yes in step S29), the controller 71 drives the tilting mechanism to tilt the picker base 5 and discard the components on the picker base 5 (step S30). In other words, in the processing in step S30, the components placed on the picker base 5 are collected in the storage 3. Then, the processing returns to step S12, and the components are resupplied from the storage 3 to the picker base 5.

Furthermore, in a case where it is determined in the processing in step S14 that the component state is “standing/protruding”, the controller 71 determines whether or not rearrangement (posture (standing)/position (protruding)) is possible (step S21). Furthermore, in step S21, the controller 71 sets the determination result to whether or not rearrangement is possible R_t. Note that the processing of determining whether or not rearrangement (posture/position) is possible in step S21 will be described in detail later.

Next, the controller determines whether, whether or not rearrangement is possible R_t set in step S21 is “rearrangement is possible” or “rearrangement is impossible” (step S22). In a case where it is determined in the processing in step S22 that “rearrangement is possible”, the controller 71 controls the supplier 4 to rearrange (change the posture or the position) the component (step S23) and picks the rearranged component (step S26).

In the processing in step S23, for example, in a case where the component is standing, an upper part of the component is pushed and rolled with the fingertips of the grasping pieces 422a or part of the component is grasped and rolled into a pickable posture. In a case where the component protrudes from the tray 51, the component is pushed out into the tray 51 with the fingertips of the grasping pieces 422a. Note that an amount of operation of the component in the processing in step S23 is calculated in the processing of determining whether or not rearrangement (posture/position) is possible in the processing in step S21.

In addition, in a case where it is determined that “rearrangement is impossible” in the processing in step S22, the controller 71 suspends the pickup operation of the component (step S28).

Furthermore, in a case where the component state is determined to be “contact” in the processing in step S14, the controller 71 performs region division processing (step S24). Furthermore, in step S24, the controller 71 sets D as success or failure (success or failure) of the region division processing. Note that the region division processing in step S24 will be described in detail later.

Next, it is determined whether the success or failure D of the region division processing performed in step S24 is “division success” or “division failure” (step S25). In a case where it is determined to be “division failure” in the processing in step S25, the controller 71 suspends the pickup operation of the component in the component region (step S28).

In addition, in a case where it is determined to be “division success” in the processing in step S25, the processing of the controller 71 returns to the processing of step S14. In the following processing, the processing is performed for each divided component region in the component region.

[Preliminary Preparation Processing]

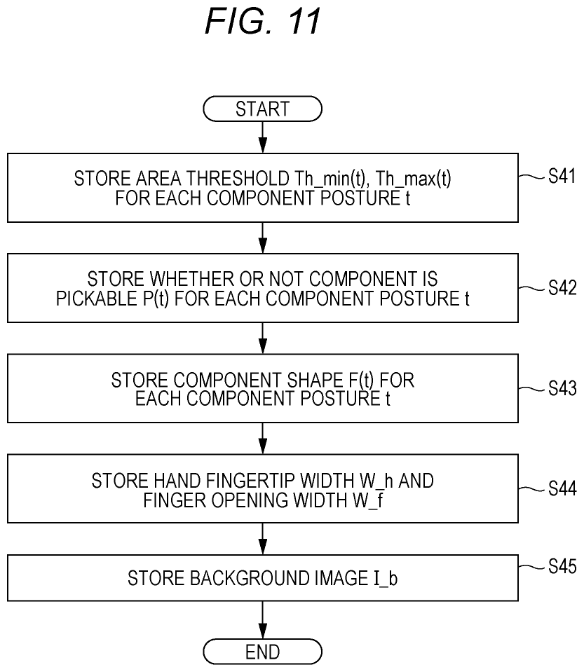

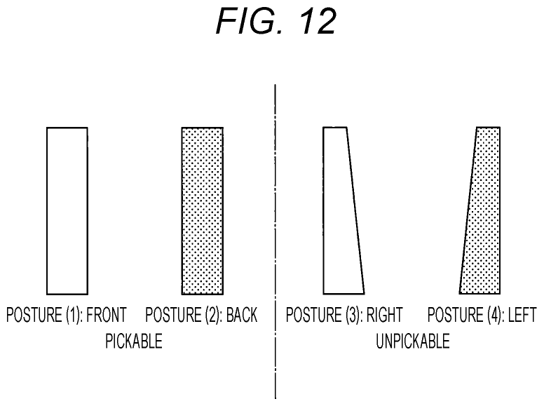

Next, the preliminary preparation processing in step S10 will be described in detail with reference to FIGS. 11 and 12.

FIG. 11 is a flowchart illustrating the preliminary preparation processing, and FIG. 12 is an explanatory diagram illustrating whether or not picking is possible in a component posture.

As illustrated in FIG. 11, first, area thresholds (a minimum area threshold Th_min(t) and a maximum area threshold Th_max(t)) for each posture t of the component to be picked up are stored in the storage 72 (step S41). Next, information on whether or not picking is possible P(t) for each component posture t is stored in the storage 72 (step S42). For example, as illustrated in FIG. 12, posture 1 (front) and posture 2 (back) are stored as postures in which picking is possible, and posture 3 (right) and posture 4 (left) are stored as postures in which picking is impossible.

Next, a component shape F(t) for each component posture t is stored in the storage 72 (step S43). Note that the information in steps S41 to S43 is created, for example, on the basis of image data obtained by capturing an image of the component with the camera 423.

Next, the hand fingertip width W_h and the finger opening width W_f (see FIG. 5) of the grasping pieces 422a of the hand 422 are stored in the storage 72 (step S44). Next, an image of the tray 51 on which no component is placed is captured by the camera 423, and the captured image data is stored in the storage 72 as a background image I_b (step S45). As a result, the preliminary preparation processing ends. Note that the entire preliminary preparation processing may be stored in the storage 72, or various types of information may be acquired from an external server.

[Component State Determination Processing]

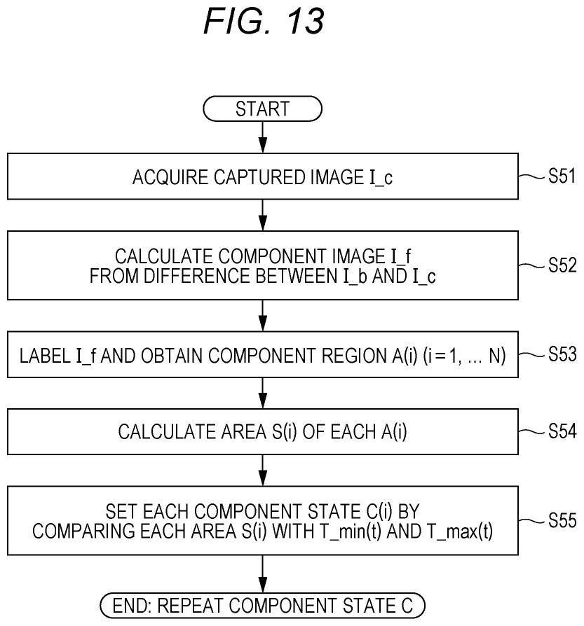

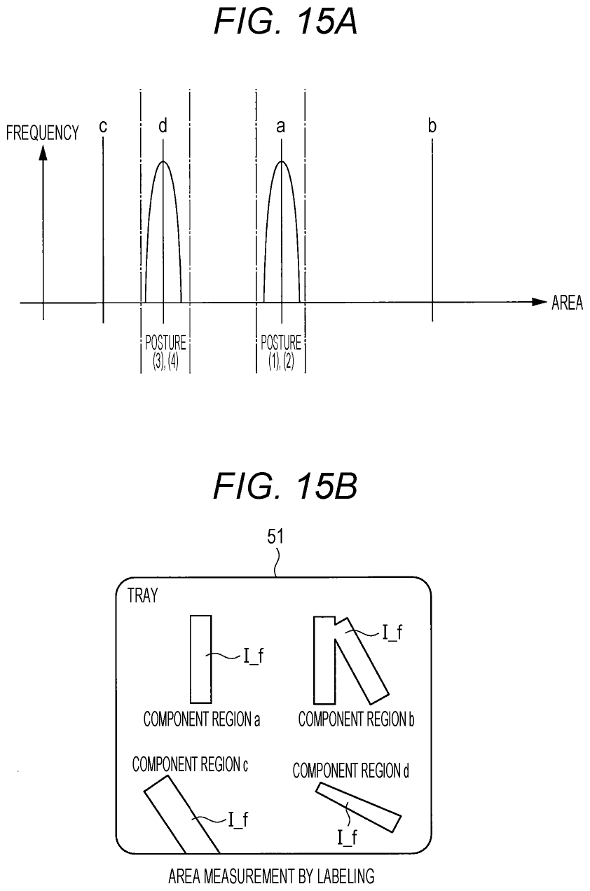

Next, the component state determination processing in step S13 will be described in detail with reference to FIGS. 13, 15A, and 15B.

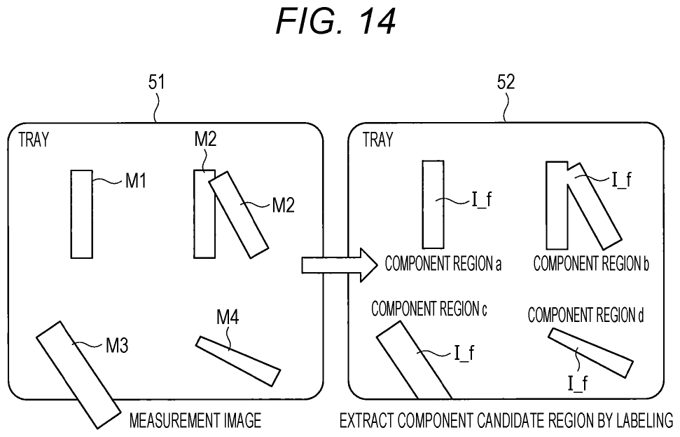

FIG. 13 is a flowchart illustrating the component state determination processing, FIGS. 14, 15A, and 15B are explanatory diagrams illustrating an example of the component state determination processing, FIG. 15A is a graph indicating a relationship between a component region and an area, and FIG. 15B is a view illustrating the component region.

As illustrated in FIG. 13, first, the controller 71 captures an image of the tray 51 on which the components are loaded with the camera 423 to acquire a captured image I_c (step S51). For example, image data in which a plurality of components M1, M2, M3, and M4 are loaded on the tray 51 as illustrated in a measurement image of FIG. 14 is acquired. Next, the controller 71 calculates a component image I_f from a difference between the background image I_b and the captured image I_c (step S52). As a result, as illustrated in FIG. 14, the component image I_f is extracted from the measurement image.

Next, the controller 71 labels the component image I_f to obtain a component region A(i) (where i=1, . . . , N) (step S53). As a result, as illustrated in FIG. 14, a first component region a, a second component region b, a third component region c, and a fourth component region d are extracted. Next, the controller 71 calculates an area S(i) of the component region A(i) (step S54).

Next, the controller 71 compares the calculated area S(i) with a threshold (T_min(t)·T_max(t)) and sets a component state C(i) (step S55). Examples of the component state C(i) include “isolation”, “contact”, and “standing/protruding”. Then, the controller 71 performs the processing in steps S54 and S55 on all the component regions A.

In the example illustrated in FIGS. 15A and 15B, the area of the first component region a falls within a range of the minimum area threshold and the maximum area threshold in the pickable posture set in advance. Thus, the component state C of the first component region a is set to “isolation”. The area of the second component region b exceeds the maximum area threshold in the pickable posture. Thus, the component state C of the second component region b is set to “contact”.

Further, the third component region c is smaller than the minimum area threshold in the unpickable posture set in advance. Thus, the component state C of the third component region c is set to “protruding”. The fourth component region d falls within a range between the minimum area threshold and the maximum area threshold in the unpickable posture. Thus, the component state of the fourth component region d is set to an unpickable posture, for example, “standing”

[Interference Determination Processing]

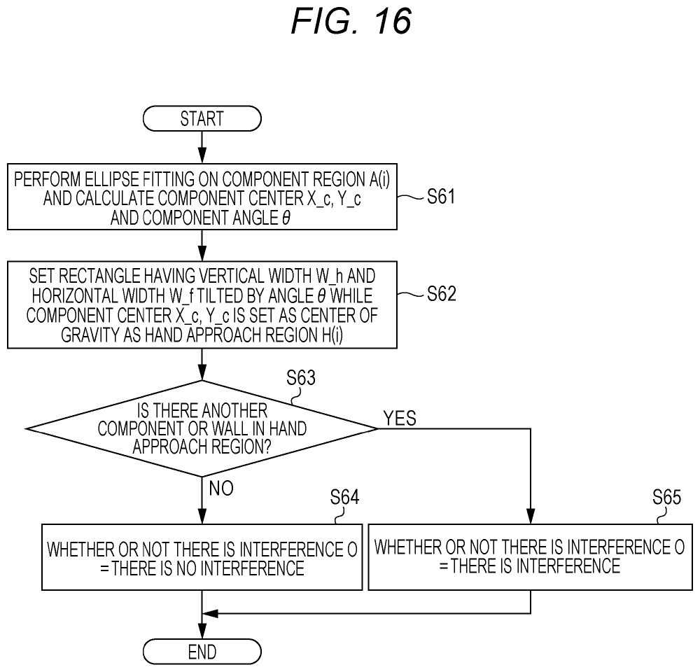

Next, the interference determination processing in step S15 will be described in detail with reference to FIGS. 16 to 18.

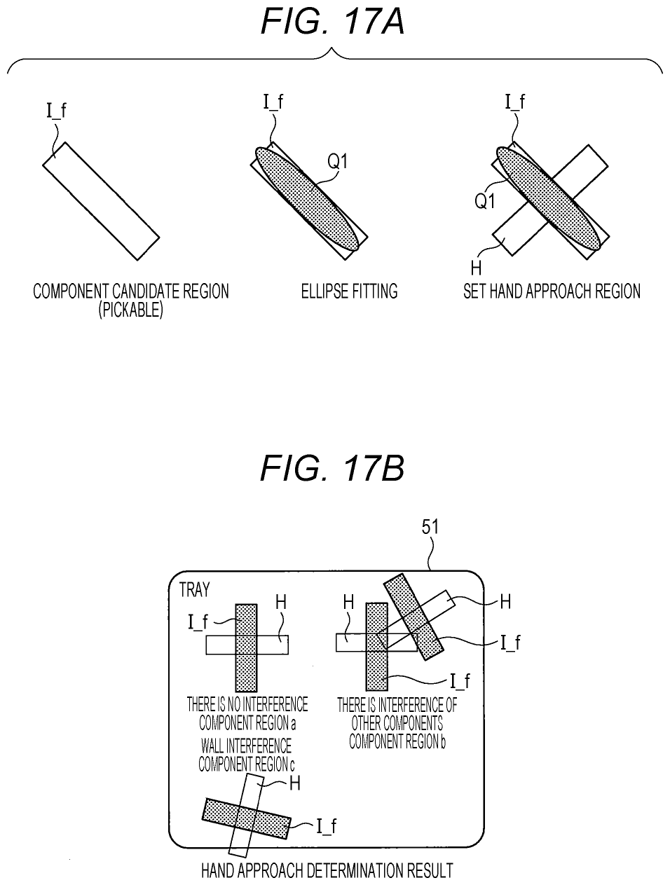

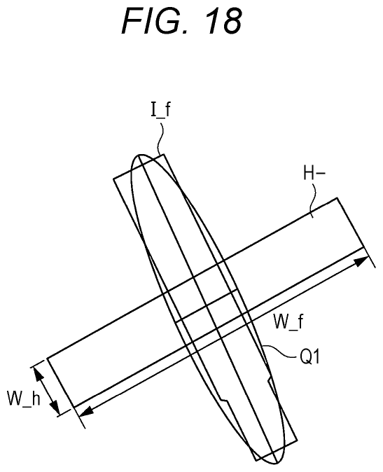

FIG. 16 is a flowchart illustrating the interference determination processing, FIGS. 17A and 17B are explanatory diagrams illustrating the interference determination processing, and FIG. 18 is an explanatory diagram illustrating ellipse fitting processing.

As illustrated in FIG. 16, the controller 71 performs ellipse fitting processing on the component region A(i) (step S61). In other words, as illustrated in FIGS. 17A and 18, an ellipse Q1 surrounding the component image I_f in each component region A is created. Then, the controller 71 calculates a component center (X_c, Y_c) and a component angle θ from the ellipse Q1.

Next, the controller 71 sets, as a hand approach region H(i), a rectangle having a vertical width W_h and a horizontal width W_f at a position tilted by an angle θ while the component center (X_c, Y_c) is set as the center of gravity for each component region A(i) (see step S62, FIG. 17A, and FIG. 18). The hand approach region H indicates a size when the hand 422 grasps the component. Then, the controller 71 determines whether or not there is another component or an obstacle such as a wall (wall plates 52, 53) of the tray 51 in the set hand approach region H(i) (step S63).

For example, as illustrated in FIG. 17B, no other component or wall exists in the hand approach region H in the first component region a, and thus, it is determined that there is no interference. In the second component region b, it is determined that there is interference because there is another component in the hand approach region H, and in the third component region c, it is determined that there is interference because there is a wall in the hand approach region H.

In the processing in step S63, in a case where it is determined that there is no other component or wall (No in step S63), the controller 71 sets whether or not there is interference O to “there is no interference” (step S64). In a case where it is determined in the processing in step S63 that there is another component or a wall (Yes in step S63), the controller 71 sets whether or not there is interference O to “there is interference” (step S65). Then, the controller 71 repeats the interference determination processing described above for all the component regions A determined to be “isolation”.

Although the example in which the ellipse fitting processing is performed on the component region A in order to set the hand approach region H for the component has been described, the present invention is not limited thereto. For example, in the preliminary preparation processing, coordinate information indicating a gravity center position of the hand approach region H with respect to the component may be stored in advance.

[Processing of Determining Whether or not Rearrangement (Position) is Possible]

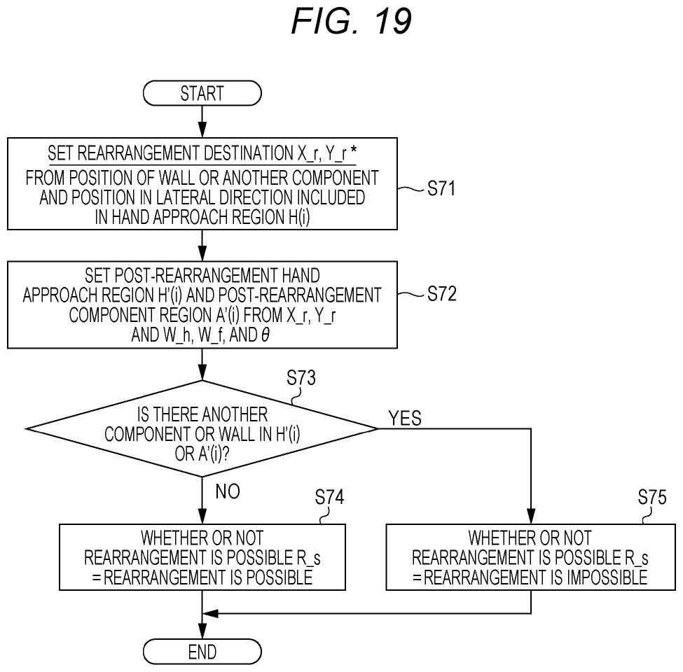

Next, the processing of determining whether or not rearrangement (position) is possible in step S17 will be described with reference to FIGS. 19 to 21.

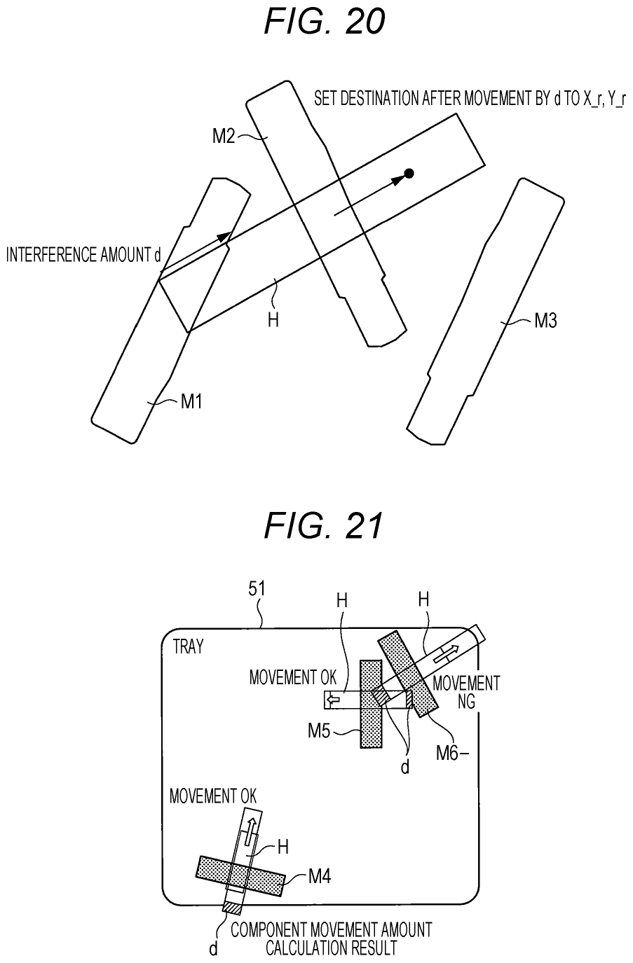

FIG. 19 is a flowchart illustrating the processing of determining whether or not rearrangement (position) is possible, and FIGS. 20 and 21 are explanatory diagrams illustrating the processing of determining whether or not rearrangement (position) is possible.

As illustrated in FIG. 19, first, a rearrangement destination (X_r, Y_r) is set from the position of the wall or the other component and the position in the lateral direction included in the hand approach region H(i) (step S71). As illustrated in FIG. 20, when a component M2 is picked, the hand approach region H interferes with a component M1. Thus, the controller 71 sets an interference amount d in a long side direction in the hand approach region H(i) in a region that interferes with the component M1 in the hand approach region H(i). Then, a position when moved by the interference amount d from the interfering position in parallel with the long side of the hand approach region H(i) is set as the rearrangement position (X_r, Y_r). Note that the interference amount d is a movement amount for rearranging the component. Then, in the processing in step S19, the controller 71 controls the supplier 4 on the basis of the calculated movement amount to move the component to the rearrangement position (X_r, Y_r) with the fingertips of the grasping pieces 422a.

Next, a post-rearrangement hand approach region H′(i) and a post-rearrangement component region A′(i) are set from the rearrangement position (X_r, Y_r), the hand fingertip width W_h, the finger opening width W_f, and the angle θ (step S72). Then, the controller 71 determines whether or not there is an obstacle such as another component (a component M3 in FIG. 20) or a wall in the post-rearrangement hand approach region H′(i) or the post-rearrangement component region A′(i) (step S73).

In the processing in step S73, in a case where it is determined that there is no other component or wall (No in step S73), the controller 71 sets whether or not rearrangement is possible R_s to “rearrangement is possible” (step S74). In a case where it is determined in the processing in step S73 that there is another component or a wall (Yes in step S73), the controller 71 sets whether or not rearrangement is possible R_s to “rearrangement is impossible” (step S75). Then, the controller 71 repeats the above-described processing of determining whether or not rearrangement (position) is possible for all the component regions A for which it is determined that there is interference.

For example, as illustrated in FIG. 21, a component M4 and a component M5 do not interfere with the wall or another component in the hand approach region H after the rearrangement, and thus, whether or not rearrangement is possible R_s is set to “rearrangement is possible”. On the other hand, the hand approach region H interferes with the wall after a component M6 is rearranged, and thus, whether or not rearrangement is possible R_s is set to “rearrangement is impossible”.

[Processing of Determining Whether or not Rearrangement (Posture/Position) is Possible]

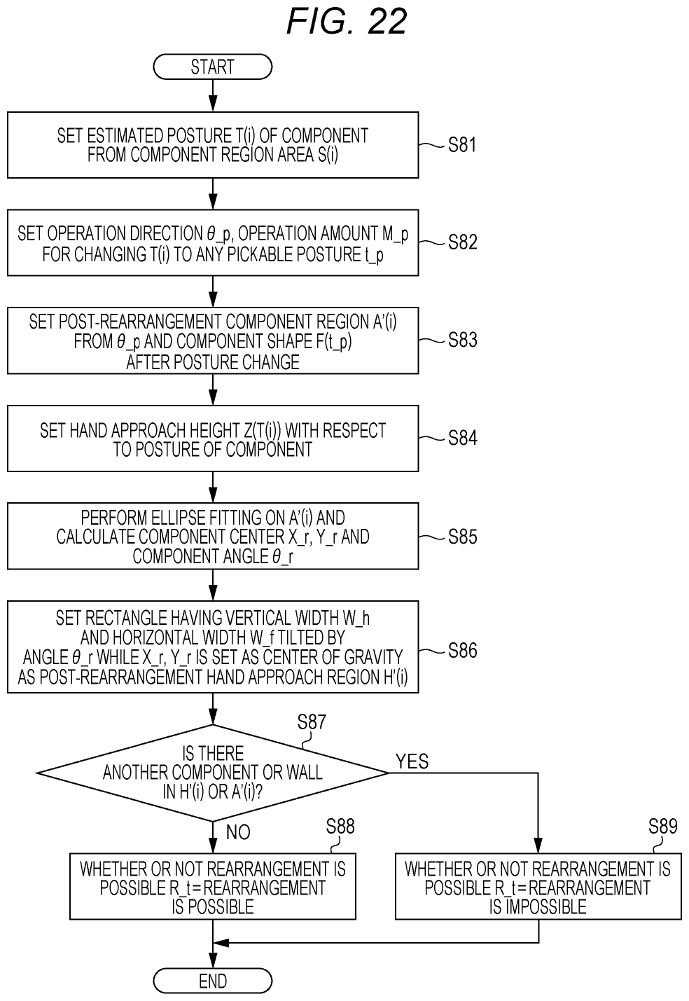

Next, the processing of determining whether or not rearrangement (posture/position) is possible in step S21 will be described with reference to FIG. 22.

FIG. 22 is a flowchart illustrating the processing of determining whether or not rearrangement (posture/position) is possible.

As illustrated in FIG. 22, first, the controller 71 sets an estimated posture T(i) of the component from the component region area S(i) acquired in the component state determination processing (step S13) (step S81). Next, the controller 71 sets an operation direction θ_p and an operation amount M_p for changing the estimated posture T(i) to the pickable posture t_p (step S82).

Next, the post-rearrangement component region A′(i) is set from the operation direction θ_p, the operation amount M_p, and a component shape F(t_p) after the posture change (step S83). In addition, a hand approach height Z(T(i)) with respect to the posture of the component is set (step S84). Here, the hand approach height Z is a height of the grasping piece 422a from the tray 51 when the posture of the component is changed.

Next, the controller 71 performs ellipse fitting on the post-rearrangement component region A′(i) to calculate the component center (X_r, Y_r) and the component angle θ_r (step S85). Then, a rectangle having a vertical width W_h and a horizontal width W_f is set to the post-rearrangement hand approach region H′(i) at a position tilted by the angle θ_r while the component center (X_r, Y_r) is set as the center of gravity (step S86). Then, the controller 71 determines whether or not there is another component or an obstacle such as a wall in the set hand approach region H′(i) or the post-rearrangement component region A′ (step S87).

In the processing in step S87, in a case where it is determined that there is no other component or wall (No in step S87), the controller 71 sets whether or not rearrangement is possible R_t to “rearrangement is possible” (step S88). In a case where it is determined in the processing in step S87 that there is another component or a wall (Yes in step S87), the controller 71 sets whether or not rearrangement is possible R_t to “rearrangement is impossible” (step S89). Then, the controller 71 repeats the above-described processing of determining whether or not rearrangement (posture/position) is possible for all the component regions A for which it is determined that the component state C is “standing/protruding”.

[Region Division Processing]

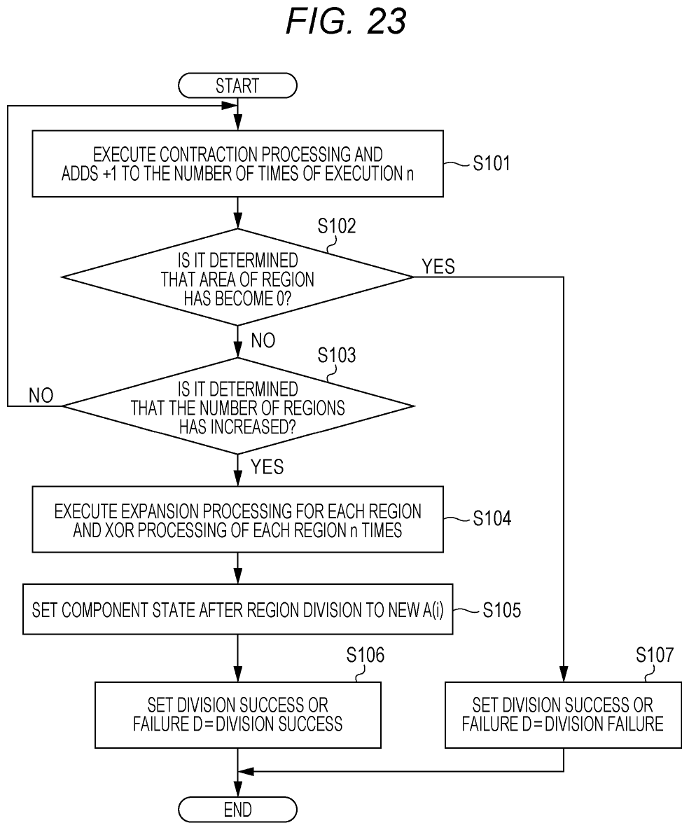

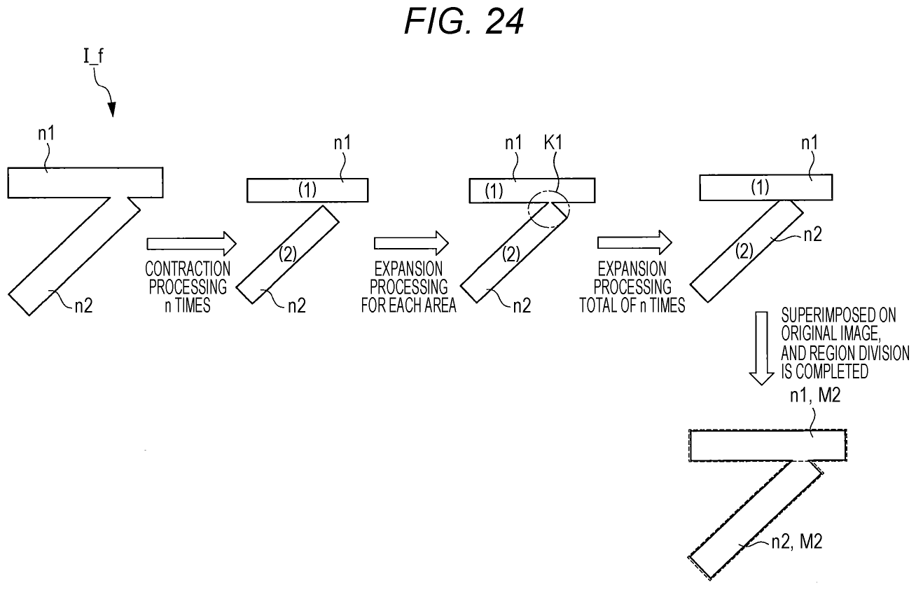

Next, the region division processing in step S24 will be described in detail with reference to FIGS. 23 and 24.

FIG. 23 is a flowchart illustrating the region division processing, and FIG. 24 is an explanatory diagram illustrating the region division processing.

As illustrated in FIG. 23, the controller 71 performs contraction processing on the component image I_f in the component region to be subjected to the region division processing (step S101). In addition, the controller 71 adds +1 to the number of times of execution n each time the contraction processing is executed. Next, the controller 71 determines whether or not the area of the region has become 0 (step S102).

In the processing in step S102, in a case where it is determined that the area of the region has become 0 (Yes in step S102), the controller 71 sets a division success/failure D to “division failure” (step S107). In a case where it is determined in the processing in step S102 that the area of the region has not become 0 (No in step S102), the processing proceeds to step S103 described later.

In the processing in step S103, the controller 71 determines whether or not the number of regions in the component image I_f has increased. In the processing in step S103, in a case where it is determined that the number of regions has not increased (No in step S103), the processing of the controller 71 returns to the processing of step S101, and the controller 71 executes the contraction processing. On the other hand, in a case where it is determined that the number of regions has increased in the processing in step S103 (Yes in step S103), the controller 71 executes expansion processing for each region and XOR processing of each region n times (the number of times that the contraction processing is executed) (step S104).

As illustrated in FIG. 24, in a case where two components are in contact or overlap with each other, the component region is divided into a first region n1 and a second region n2 by executing the contraction processing n times. By executing the expansion processing, the first region n1 and the second region n2 come into contact with each other. Then, in the XOR processing, the image data of an area K1 where the first region n1 and the second region n2 overlap is deleted. After the expansion processing is executed n times, the image is superimposed on the original image.

Next, the controller 71 sets the component state after the region division as a new component region A(i) (step S105). In other words, the first region n1 and the second region n2 are set as different component regions A. Then, the controller 71 sets the division success/failure D to “division success” (step S106). In addition, the controller 71 repeats the region division processing described above for all the component regions A for which it is determined that the component state C is “contact”.

Note that the region division processing is not limited to the above-described method, and various other methods are applied.

According to the component supply device and the component supply method of the present invention, the unpickable component specifier 801 specifies an unpickable component among the plurality of components on the tray 51. This makes it possible to adjust only the position and the posture of an unpickable component. As a result, the position and the posture of the unpickable component can be adjusted in a state where pickable components are loaded on the tray 51.

Further, a state of the specified unpickable component is calculated, and a pickable state is calculated. This makes it possible to reduce the number of times of adjustment operation for bringing an unpickable component into a pickable state, so that it is possible to improve efficiency of the pickup operation.

Furthermore, the state of the component is sorted into various types such as “isolation”, “contact”, “standing/protruding”, and “there is interference or no interference” according to the posture and position. This makes it possible to appropriately calculate the movement amount and the operation amount for rearranging an unpickable component according to the type of the state of the component. This eliminates the necessity of the operation of adjusting the rearranged component again, so that it is possible to further improve the efficiency of the pickup operation.

The embodiment has been described above with the functions and effects thereof. However, the present invention is not limited to the above-described embodiment, and various modifications can be made without departing from the gist of the invention described in the claims.

In addition, some or all of the above-described components, functions, processors, and the like, may be implemented by hardware, for example, by designing an integrated circuit, or the like. In addition, each component, function, and the like, described above may be implemented by software by a processor interpreting and executing a program for implementing each function. Information such as a program, a table, and a file for implementing each function can be stored in a recording device such as a memory, a hard disk, and a solid state drive (SSD), or a recording medium such as an IC card, an SD card, and a DVD.

In the present specification, words such as “parallel” and “orthogonal” are used, but these do not strictly mean only “parallel” and “orthogonal” and may indicate a state of “substantially parallel” or “substantially orthogonal” including “parallel” and “orthogonal” and in a range in which the function can be exhibited.

Although embodiments of the present invention have been described and illustrated in detail, the disclosed embodiments are made for purposes of illustration and example only and not limitation. The scope of the present invention should be interpreted by terms of the appended claims.

What is claimed is:

1. A component supply device comprising:
a picker base on which a component is to be loaded;
a supplier that picks up the component loaded on the picker base and supplies the component to a predetermined position;
a detector that detects the component loaded on the picker base; and
a hardware processor that determines a state of the component loaded on the picker base, on a basis of information detected by the detector,
wherein the hardware processor determines whether the component is a component that is pickable or a component that is unpickable by the supplier on a basis of the state of the component, and
calculates an operation amount for adjusting the component that is unpickable to a pickable state and adjusts only a state of the component that is unpickable by an adjuster on a basis of the calculated operation amount.

2. The component supply device according to claim 1,
wherein the adjuster is the supplier, and
the hardware processor controls the supplier to adjust a state of the component that is unpickable on a basis of the calculated operation amount.

3. The component supply device according to claim 1,
wherein the hardware processor sorts the state of the component into a plurality of types on a basis of the information detected by the detector.

4. The component supply device according to claim 3,
wherein the hardware processor calculates an operation amount for adjusting the component that is unpickable to a pickable state according to a type indicating a state of the sorted component.

5. The component supply device according to claim 3, further comprising:
a storage that stores a minimum area threshold and a maximum area threshold for each posture of the component,
wherein the hardware processor determines whether a state of the component is a component that is pickable or a component that is unpickable on a basis of the information detected by the detector and the minimum area threshold and the maximum area threshold.

6. The component supply device according to claim 5,
wherein the hardware processor determines a posture of the component on a basis of the information detected by the detector and the minimum area threshold and the maximum area threshold.

7. The component supply device according to claim 5,
wherein the storage stores a hand approach region indicating a size when the supplier picks up the component, and
the hardware processor sets the hand approach region for the component on a basis of the information detected by the detector and determines whether the component is a component that is pickable or a component that is unpickable.

8. The component supply device according to claim 7,
wherein the hardware processor determines whether the component is a component that is pickable or a component that is unpickable according to whether or not there is another component or an obstacle in the hand approach region.

9. A component supply method comprising:
loading a component on a picker base;
detecting the component loaded on the picker base and determining a state of the component;
determining whether the component is a component that is pickable or a component that is unpickable by a supplier on a basis of the state of the component;
calculating an operation amount for adjusting the component that is unpickable to a pickable state; and
adjusting only a state of the component that is unpickable on a basis of the calculated operation amount.

10. A non-transitory recording medium storing a computer readable program causing a computer to execute:
detecting a component loaded on a picker base and determining a state of the component;
determining whether the component is a component that is pickable or a component that is unpickable by a supplier on a basis of the state of the component;
calculating an operation amount for adjusting the component that is unpickable to a pickable state; and
adjusting only a state of the component that is unpickable on a basis of the calculated operation amount.
